(19) United States
(12) Patent Application Publication
(10) Pub. No.: US 2026/0150533 A1
(43) Pub. Date: May 28, 2026

(54) ORGANIC LIGHT EMITTING DISPLAY APPARATUS

(71) Applicant: LG Display Co., Ltd., Seoul (KR)

(72) Inventors: Dae Gyu JO, Paju-si (KR); Chi Heon KIM, Paju-si (KR)

(73) Assignee: LG Display Co., Ltd., Seoul (KR)

(21) Appl. No.: 19/188,729

(22) Filed: Apr. 24, 2025

(30) Foreign Application Priority Data
Nov. 26, 2024 (KR) 10-2024-0171381

(51) Int. Cl. H10K 59/127; H10K 59/123; H10K 59/131; H10K 59/40

(52) U.S. Cl. CPC H10K 59/1275; H10K 59/123; H10K 59/131; H10K 59/40

(57) ABSTRACT

An organic light emitting display apparatus including a substrate including a display area and a non-display area at a periphery of the display area; a plurality of display pads provided in the non-display area and configured to transfer a signal to the display area; a driving integrated circuit (IC) electrically connected to the plurality of display pads through an adhesive member in the non-display area; a first dam disposed at a first corner portion of the driving IC; and a second dam disposed at the first corner portion of the driving IC. Further, the first dam and the second dam are spaced apart from each other with the first corner portion of the driving IC therebetween to form an adhesive flow path between the first dam and the second dam. Thus, the adhesive member is disposed in the adhesive flow path formed between the first dam and the second dam.

### CROSS-REFERENCE TO RELATED APPLICATIONS

This application claims priority to Korean Patent Application No. 10-2024-0171381, filed in the Republic of Korea on Nov. 26, 2024, the entire contents of which is hereby expressly incorporated by reference into the present application.

### BACKGROUND

### Field of the Invention

The present disclosure relates to an organic light emitting display apparatus.

### Discussion of the Related Art

Organic light emitting display apparatuses are self-emitting display apparatuses and can be manufactured to be lightweight and thin because a separate light source is not needed, unlike liquid crystal display (LCD) apparatuses. Also, organic light emitting display apparatuses are favorable for power consumption, based on a low voltage driving, and are also good in a color implementation, response time, viewing angle, and contrast ratio (CR), and thus are being researched as displays of various technology fields.

In addition, organic light emitting display apparatuses include a display panel having a display area and a non-display area at a periphery of the display area and including a display pad disposed in the non-display area to transfer a signal to the display area. Further, a driving integrated circuit (IC) electrically connected to a display pad is further provided in the non-display area of a substrate through a bonding process.

### SUMMARY

During a bonding process on the driving IC and a display pad, a certain amount of pressure is applied to a region to which driving IC is attached, and therefore a panel strain and/or a panel crack can occur in the region to which the driving IC is attached.

To overcome the aforementioned problem of the related art, the present disclosure provides a display apparatus including a plurality of dams having a certain height formed through patterning from a surface of a substrate to be symmetrical with both sides with a certain distance with respect to a corner portion at an outer boundary portion of a driving IC. Therefore, an adhesive member attaching the driving IC to the substrate including a panel can be easily squeezed out toward the corner portion of the driving IC in the bonding process of the driving IC.

The objects of the present disclosure are not limited to the objects described above, and other objects not described herein will be clearly understood by those of ordinary skill in the art from descriptions below.

To achieve these objects and other advantages and in accordance with the purpose of the disclosure, as embodied and broadly described herein, an organic light emitting display apparatus includes a substrate including a display area and a non-display area at a periphery of the display area, a plurality of display pads provided in the non-display area and configured to transfer a signal to the display area, a driving integrated circuit (IC) electrically connected to plurality of display pads through an adhesive member in the non-display area, and a plurality of dams disposed in a peripheral region of the driving IC and formed to have a certain height from a surface of the substrate. Further, the plurality of dams are spaced apart from each other with a corner portion of the driving IC therebetween.

An organic light emitting display apparatus according to another embodiment of the present disclosure includes a substrate including a display area and a non-display area at a periphery of the display area, a plurality of display pads provided in the non-display area and configured to transfer a signal to the display area, an insulation layer covering an upper portion of the substrate and some of the plurality of display pads, a driving IC electrically connected to the display pad and disposed in the non-display area, and a plurality of dams disposed in a peripheral region of the driving IC and formed to have a certain height from a surface of the substrate, an align key provided on the driving IC, an organic material disposed between the driving IC where the display pads are provided in a non-display area and the substrate thereunder, a first dam disposed at an outer boundary of one side with respect to a corner portion of the driving IC, a second dam disposed at an outer boundary of the other side with respect to the corner portion of the driving IC, and an auxiliary dam additionally installed in the corner portion of the driving IC, thereby increasing the amount of squeeze-out of an organic material.

Other details of embodiments are included in the detailed description of the disclosure and the drawings.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is an exploded perspective view illustrating an organic light emitting display apparatus with a touch sensor integrated thereinto;

FIG. 2 is a plan view illustrating the organic light emitting display apparatus illustrated in FIG. 1;

FIG. 3 is a diagram illustrating an organic light emitting display apparatus taken along line I-I′ of FIG. 2;

FIG. 4 is a plan view illustrating in detail a region A of FIG. 2;

FIG. 5 is a diagram illustrating an organic light emitting display apparatus taken along line II-II′ of FIG. 2;

FIG. 6A is a diagram illustrating a cross-sectional view of a portion of an organic light emitting display apparatus according to a comparative example of the present disclosure;

FIG. 6B is a diagram illustrating a schematic view of a portion of an organic light emitting display apparatus according to a comparative example of the present disclosure;

FIG. 7A is a diagram schematically illustrating a plan view of an organic light emitting display apparatus according to a first embodiment of the present disclosure;

FIG. 7B is a diagram schematically illustrating a perspective view of an organic light emitting display apparatus according to a first embodiment of the present disclosure;

FIG. 7C is a diagram illustrating an organic light emitting display apparatus taken along line A-A′ of FIG. 7A;

FIG. 7D is a diagram schematically illustrating a cross-sectional view of an organic light emitting display apparatus taken along line B-B′ of FIG. 7A;

FIG. 8A is a diagram schematically illustrating a plan view of an organic light emitting display apparatus according to a second embodiment of the present disclosure;

FIG. 8B is a diagram schematically illustrating a perspective view of an organic light emitting display apparatus according to a second embodiment of the present disclosure;

FIG. 9A is a diagram schematically illustrating a plan view of an organic light emitting display apparatus according to a third embodiment of the present disclosure;

FIG. 9B is a diagram schematically illustrating a perspective view of an organic light emitting display apparatus according to a third embodiment of the present disclosure;

FIG. 10 is a diagram schematically illustrating a perspective view of an organic light emitting display apparatus according to a fourth embodiment of the present disclosure;

FIG. 11 is a diagram schematically illustrating a perspective view of an organic light emitting display apparatus according to a fifth embodiment of the present disclosure;

FIG. 12 is a diagram schematically illustrating a perspective view of an organic light emitting display apparatus according to a sixth embodiment of the present disclosure;

FIG. 13A is a diagram schematically illustrating a perspective view of an organic light emitting display apparatus according to a seventh embodiment of the present disclosure;

FIG. 13B is a diagram schematically illustrating a cross-sectional view of an organic light emitting display apparatus taken along line C-C′ of FIG. 13A; and

FIG. 13C is a diagram schematically illustrating a cross-sectional view of an organic light emitting display apparatus taken along line D-D′ of FIG. 13A.

### DETAILED DESCRIPTION OF THE DISCLOSURE

Hereinafter, preferable embodiments of the present disclosure will be described in detail with reference to the accompanying drawings. In the present disclosure, like reference numbers denote substantially like elements. Also, the terms of elements used herein can be selected in consideration of the easiness of description of the present disclosure and can differ the terms of components of a real product.

Shapes, sizes, ratios, angles, and numbers illustrated in the drawings for describing various embodiments of the present disclosure are exemplary, and thus, the present disclosure is not limited to the illustrations of the drawings. Herein, like reference numerals. When ‘comprise’, ‘have’, ‘consist of’, ‘constitute’, or ‘include’ described herein is used, unless ‘only˜’ is used, another part can be added. When an element is described in the singular form, this can include the plural number unless explicitly described.

In construing an element included in various embodiments of the present disclosure, the element is construed to include an error range even without separate explicit description. In describing various embodiments of the present disclosure, when a position relationship, for example, a position relationship between two elements is described to be ‘on˜’, ‘over ˜’, ‘under˜’, ‘next to ˜’, ‘side˜’, ‘upper˜’ or ‘lower˜’, one or more other elements can be disposed between two elements unless ‘just’ or ‘direct’ is used.

In describing various embodiments of the present disclosure, when a time relationship, for example, when the temporal order is described to be ‘after ˜’, ‘subsequent to ˜’, ‘next to ˜’ or ‘before˜’, this can include a discontinuous case unless ‘just’ or ‘direct’ is used. Also, the terms ‘first˜’ and ‘second˜’ can be used for describing various elements, but the terms are merely used for distinguishing like or similar elements from each other. Therefore, in the present disclosure, unless separately described, an element modified by ‘first˜’ can be the same as an element modified by ‘second˜’ in the technical idea of the present disclosure.

Features of various embodiments of the present disclosure can be partially or overall coupled to or combined with each other and can be variously inter-operated with each other and driven technically as those skilled in the art can sufficiently understand. The embodiments of the present disclosure can be performed independently from each other, or can be performed together in co-dependent relationship.

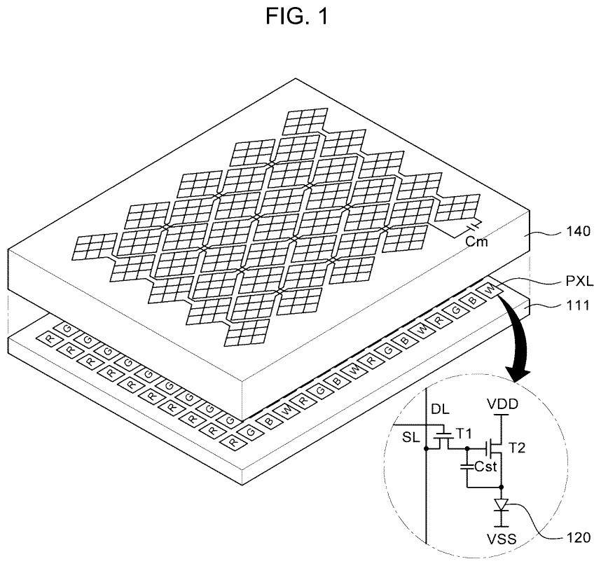

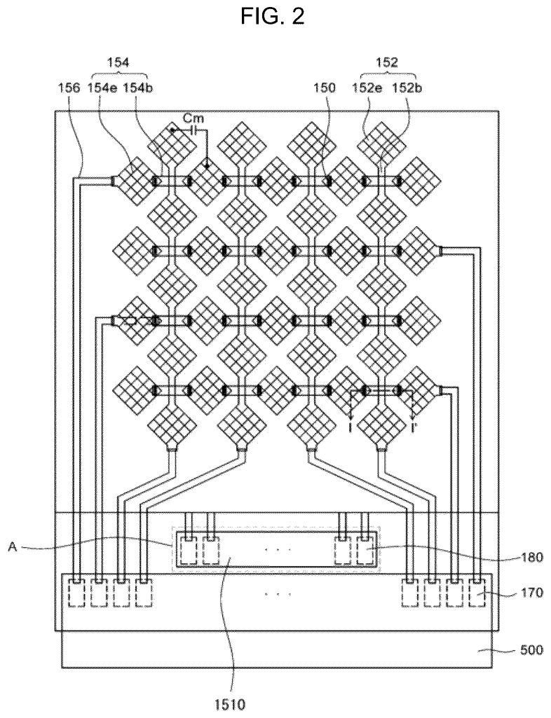

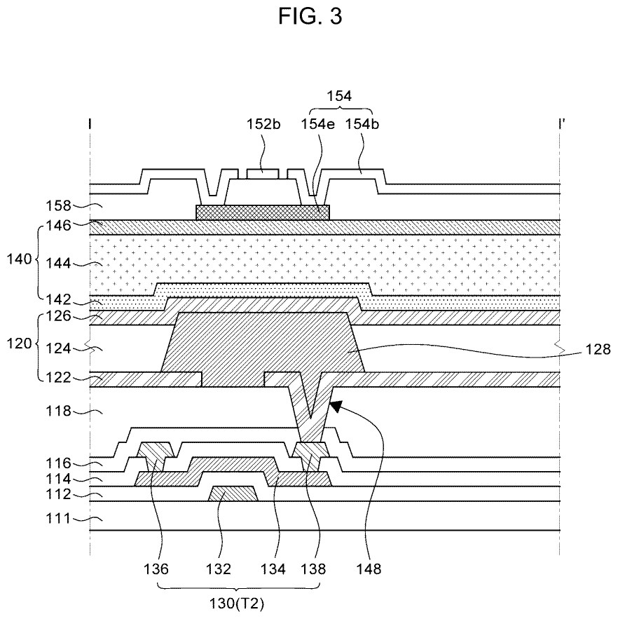

Hereinafter, a display apparatus according to an embodiment of the present disclosure will be described with reference to the accompanying drawings. In particular, FIG. 1 is an exploded perspective view illustrating an organic light emitting display apparatus with a touch sensor integrated thereinto, FIG. 2 is a plan view illustrating the organic light emitting display apparatus illustrated in FIG. 1, and FIG. 3 is a diagram illustrating an organic light emitting display apparatus taken along line I-I′ of FIG. 2.

Referring to FIGS. 1 to 3, an organic light emitting display apparatus including a touch sensor according to the present disclosure can sense a variation of a mutual capacitance (a touch sensor) Cm based on a user touch through touch electrodes 152e and 154e to detect whether there is a touch and a touch position, during a touch period. Also, the organic light emitting display apparatus can display an image through a unit pixel including a light emitting device 120. The unit pixel can be configured with red (R), green (G), and blue (B) subpixels PXL, or can be configured with red (R), green (G), blue (B), and white subpixels PXL.

Further, the organic light emitting display apparatus can include a plurality of subpixels PXL which are arranged as a matrix type on a substrate 111, an encapsulation part 140 disposed on the plurality of subpixels PXL, and a mutual capacitor Cm disposed on the encapsulation part 140. Each subpixel PXL can include a pixel driving circuit and the light emitting device 120 contacting the pixel driving circuit.

When a scan pulse is supplied to a scan line SL, a switching transistor T1 can be turned on, and thus, a data signal supplied to a data line DL can be supplied to a storage capacitor Cst and a gate electrode of a driving transistor T2. In response to the data signal supplied to the gate electrode of the driving transistor T2, the driving transistor T2 can control a current supplied to the light emitting device 120 through a high voltage VDD supply line and can thus adjust the amount of light emission by the light emitting device 120.

Moreover, even when the switching transistor T1 is turned off, the driving transistor T2 can supply a certain current until a data signal of a next frame is supplied thereto, based on a voltage charged in the storage capacitor Cst, and thus, can allow the light emitting device 120 to maintain light emission. Such a driving thin film transistor (TFT) T2 130, as illustrated in FIG. 3, can include a gate electrode 132, a semiconductor layer 134 overlapping the gate electrode 132 with a gate insulation layer 112 therebetween, and source and drain electrodes 136 and 138 which are formed on an interlayer insulation layer 114 to contact the semiconductor layer 134. The gate electrode 132 can include various conductive material, and for example, can include at least one of magnesium (Mg), aluminum (Al), nickel (Ni), chrome (Cr), molybdenum (Mo), tungsten (W), and gold (Au), or an alloy thereof. Further, the gate insulation layer 112 can include an insulating material such as silicone oxide (SiOx) or silicone nitride (SiNx), and moreover, can include an insulating organic material.

Here, the semiconductor layer 134 can be formed of at least one of an amorphous semiconductor material, a polycrystalline semiconductor material, and an oxide semiconductor material on the gate insulation layer 112. A planarization layer 118 can be disposed on a TFT. In particular, the planarization layer 118 can include a contact hole which exposes the drain electrode 138 of the TFT. The planarization layer 118 also allows a roughness of a substrate surface to be uniform, so as to coat an emission stack 124 configuring an organic light emitting device in a smoothly flat state. The planarization layer 118 can also be configured in various shapes and can be formed of an organic insulation layer such as benzocyclobutene (BCB) or acryl or an inorganic insulation layer such as (SiNx) or (SiOx), or can be variously modified to be configured as a single layer or a double layer or a multilayer.

In addition, the light emitting device 120 can include an anode electrode 122, at least one emission stack 124 formed on the anode electrode 122, and a cathode electrode 126 formed on the emission stack 124. The anode electrode 122 can be electrically connected to the drain electrode 138 of the driving TFT T2 130 exposed through a pixel contact hole 148 passing through a passivation layer 116.

Further, the at least one emission stack 124 can be formed on the anode electrode 122 of an emission region provided by a bank 128. In particular, the at least one emission stack 124 can be formed by stacking a hole-related layer, an organic emission layer, and an electron-related layer on the anode electrode 122 in order or reverse order. Also, the emission stack 124 can include first and second emission stacks which are opposite to each other with a charge generating layer (CGL) therebetween. In this instance, an organic emission layer of one of the first and second emission stacks can generate blue light, and an organic emission layer of the other of the first and second emission stacks can generate yellow-green light, and thus, white light can be generated through the first and second emission stacks. Also, the white light generated by the emission stack 124 can be incident on a color filter disposed on or under the emission stack 124, and thus, a color image can be implemented. Furthermore, each of the emission stacks 124 can generate color light corresponding to each subpixel to implement a color image, without a separate color filter. That is, an emission stack 124 of a red (R) subpixel can generate red light, an emission stack 124 of a green (G) subpixel can generate green light, and an emission stack 124 of a blue (B) subpixel can generate blue light.

In addition, the cathode electrode 126 can be formed to be opposite to the anode electrode 122 with the emission stack 124 therebetween and can be connected to a low voltage VSS supply line. Further, the bank 128 can be formed in the other region except the emission region. Therefore, the bank 128 can include a bank hole which exposes the anode electrode 122 corresponding to the emission region. The bank 128 can also include an inorganic insulation layer, such as (SiNx) or (SiOx), or an organic insulation layer such as BCB, acrylic resin, or imide-based resin.

Further, a spacer can be further formed on the bank 128. In particular, the spacer can be formed of an organic layer such as acrylic resin, epoxy resin, phenolic resin, polyamide resin, or polyimide resin. The spacer can also be omitted.

In addition, the encapsulation part 140 prevents external water or oxygen from penetrating into the light emitting device 120 vulnerable to external water or oxygen. In more detail, the encapsulation part 140 can include a plurality of inorganic encapsulation layers 142 and 146 and an organic encapsulation layer 144 disposed between the inorganic encapsulation layers 142 and 146, and the inorganic encapsulation layer 146 can be disposed in an uppermost layer. In this instance, the encapsulation part 140 can include at least two inorganic encapsulation layers 142 and 146 and at least one organic encapsulation layer 144. A structure of the encapsulation part 140 where the organic encapsulation layer 144 is disposed between the first and second inorganic encapsulation layers 142 and 146. As shown in FIG. 3, the first inorganic encapsulation layer 142 can be formed on the substrate 111 where the cathode electrode 126 is formed closest to the light emitting device 120. In addition, the first inorganic encapsulation layer 142 can include an inorganic insulating material such as SiNx, SiOx, silicone oxynitride (SiON), or aluminum oxide (A 1203) capable of low temperature deposition. Accordingly, the first inorganic encapsulation layer 142 can be deposited in a low temperature atmosphere, and thus, can prevent the emission stack 124 vulnerable to a high temperature atmosphere from being damaged when performing a deposition process of the first inorganic encapsulation layer 142.

Further, the organic encapsulation layer 144 can alleviate stress between layers caused by bending of an organic light emitting display apparatus and can reinforce planarization performance. In this instance, silicone oxycarbide (SiOCz) can be used, or acryl or epoxy-based resin can be used, but the present disclosure is not limited thereto. For example, when the organic encapsulation layer 144 is formed of SiOCz, the organic encapsulation layer 144 can be formed by a chemical vapor deposition (CVD) process. SiOCz can be classified into an inorganic material or an organic material under a specific condition. To provide a detailed description, SiOCz can be changed in flowability, based on an atom ratio of carbon to silicone (C/Si). For example, when the flowability of SiOCz is worsened, SiOCz can have a characteristic similar to an inorganic material, and thus, a performance of compensating for a foreign material can be degraded, and when the flowability of SiOCz is improved, SiOCz can have a characteristic similar to an organic material, and thus, a performance of compensating for a foreign material can be enhanced. Also, a C/Si ratio of SiOCz can be controlled by adjusting a ratio of hexamethyldisiloxane (HM DSO) to oxygen (O₂) when performing a CV D process. Particularly, when the organic encapsulation layer 144 includes SiOCz, a thickness of the encapsulation part 140 can be implemented to be very thin, and a thickness of an organic light emitting display apparatus can be reduced.

For example, when the organic encapsulation layer 144 includes acryl or epoxy-based resin, the organic encapsulation layer 144 can be formed by a slit coating process or a screen printing process. In this instance, the epoxy-based resin can use bisphenol-A-epoxy of high viscosity or bisphenol-F-epoxy of low viscosity. The organic encapsulation layer 144 can further include additives. For example, a wetting agent for decreasing a surface tension of resin so as to improve the uniformity of resin, a leveling agent for improving the surface flatness of resin, and a defoaming agent for removing an air bubble included in resin can be further added as additives. The organic encapsulation layer 144 can further include an initiator. For example, an antimony-based initiator or an anhydride-based initiator for curing liquid resin can be used for improving a chain reaction based on heat.

Additionally, when a temperature of resin increases, a viscosity of liquid resin can be rapidly lowered, and then, as curing starts when a certain time elapses, viscosity can rapidly increase, and thus, curing can be completed. However, resin can have high flowability for a certain time for which viscosity decreases.

In addition, the organic encapsulation layer 144 can cover foreign materials or particles occurring in a process. For example, a defect caused by a crack occurring due to foreign materials or particles can be in the first inorganic encapsulation layer 142. However, flexion and foreign materials can be covered by the organic encapsulation layer 144, and an upper surface of the organic encapsulation layer 144 can be planarized. That is, the organic encapsulation layer 144 can compensate for foreign materials and can planarize a display area. As a result, the organic encapsulation layer 144 can be referred to as a compensation layer.

Further, the second inorganic encapsulation layer 146 can be formed to cover an upper surface and a side surface of the organic encapsulation layer 144 and an upper surface of the first inorganic encapsulation layer 142 exposed by the organic encapsulation layer 144. Therefore, the second inorganic encapsulation layer 146 can minimize or prevent the penetration of external water or oxygen into the first inorganic encapsulation layer 142 and the organic encapsulation layer 144. Also, the second inorganic encapsulation layer 146 can include an inorganic insulating material such as SiNx, SiOx, SiON, or Al₂O₃. The first and second inorganic encapsulation layers 142 and 146 can also include the same material and can each be configured with a plurality of layers.

Further, the encapsulation part 140 can be formed to have a total thickness of about 10 μm to about 30 μm, so as to sufficiently prevent the penetration of water from the outside. Moreover, the encapsulation part 140 can at least cover a display area, and thus, a side portion of the encapsulation part 140 can be disposed in a non-display area. Also, only an inorganic encapsulation layer of the encapsulation part 140 can be exposed at a side portion of the non-display area, and thus, the penetration of external air can be effectively prevented.

That is, the organic encapsulation layer 144 can be disposed in an inward region to be closer to the display area than the inorganic encapsulation layers 142 and 146 thereon or thereunder, and the second inorganic encapsulation layer 146 thereon can be formed to extend toward the non-display area with respect to the organic encapsulation layer 144 to contact a side surface of the organic encapsulation layer 142.

As shown in FIG. 3, a touch sensing line 154 and a touch driving line 152 can be disposed on the encapsulation part 140 to intersect each other with a touch insulation layer 158 therebetween. The mutual capacitor Cm can also be formed at an intersection portion of the touch sensing line 154. Therefore, the mutual capacitor Cm can be charged with an electric charge by a touch driving pulse supplied to the touch driving line 152 and can discharge the charged electric charge to the touch sensing line 154, and thus, can function as a touch sensor.

In addition, as shown, the touch driving line 152 can include a plurality of first touch electrodes 152e and a plurality of first bridges 152b electrically connecting the plurality of first touch electrodes 152e with each other. The first touch electrodes 152e can be disposed apart from each other by a certain interval in a Y direction (a first direction), on the second inorganic encapsulation layer 146. Each first touch electrode 152e can be electrically connected to an adjacent first touch electrode 152e through a corresponding first bridge 152b.

A Iso, a second bridge 154b can be formed on the touch insulation layer 158 and can be exposed through a touch contact hole 150 passing through the touch insulation layer 158, and thus, can be electrically connected to the second touch electrode 154e. The second bridge 154b, like the first bridge 152b, can be disposed to overlap the bank 120 and can thus prevent an aperture ratio from being reduced by the first and second bridges 152b and 154b.

Each of the first and second touch electrodes 152e and 154e and the first and second bridges 152b and 154b can be formed in a single-layer or multi-layer structure by using a conductive layer which is strong in corrosion resistance and acid resistance and good in conductivity like Al, Ti, Cu, and Mo. For example, each of the first and second touch electrodes 152e and 154e and the first and second bridges 152b and 154b can be formed in a three-layer structure of Ti/Al/Ti or Mo/Al/Mo which are sequentially stacked.

In addition, each of the first and second touch electrodes 152e and 154e and the first and second bridges 152b and 154b can be formed as a mesh type. Therefore, a resistance and a capacitance of each of the first and second touch electrodes 152e and 154e and the first and second bridges 152b and 154b can be reduced, and a line width of each of the first and second touch electrodes 152e and 154e and the first and second bridges 152b and 154b having a mesh type can be very thin, thereby preventing an aperture ratio and a transmittance from being reduced by the first and second touch electrodes 152e and 154e and the first and second bridges 152b and 154b having a mesh type.

Further, each of the touch driving line 152 and the touch sensing line 154 according to the present disclosure can be connected to a touch driver 500 through a routing line 156 and a touch pad 170 disposed in the non-display (bezel) area. Therefore, the routing line 156 can transfer a touch driving pulse, generated by the touch driver 500, to the touch driving line 152 through the touch pad 170 and can transfer a touch signal from the touch sensing line 154 to the touch pad 170. Also, the routing line 156 can be disposed between each of the first and second touch electrodes 152e and 154e and the touch pad 170 and can be directly connected to each of the first and second touch electrodes 152e and 154e without a separate contact hole. The routing line 156 can also be formed by the same mask process as the first bridge 152b by using the same material as that of the first bridge 152b, and thus, can be protected by the touch insulation layer 158.

In addition, the routing line 156 connected to the first touch electrode 152e, as illustrated in FIG. 2, can extend to at least one of an upper side and a lower side of the display area and can be connected to the touch pad 170. The routing line 156 connected to the second touch electrode 154e can also extend to at least one of a left side and a right side of the display area and can be connected to the touch pad 170. Also, the arrangement of the routing line 156 is not limited to the structure of FIG. 2 and can be variously modified based on a design of a display apparatus.

Referring to FIGS. 1 and 2, an organic light emitting display apparatus according to the present disclosure can include a driving IC 1510 of a chip on panel (COP) type so as to drive data lines DL. The COP type can be a type where a driving chip is directly formed on the substrate 111. The driving IC 1510 can also be electrically connected to a display pad 180 which outputs a data signal to the data lines DL.

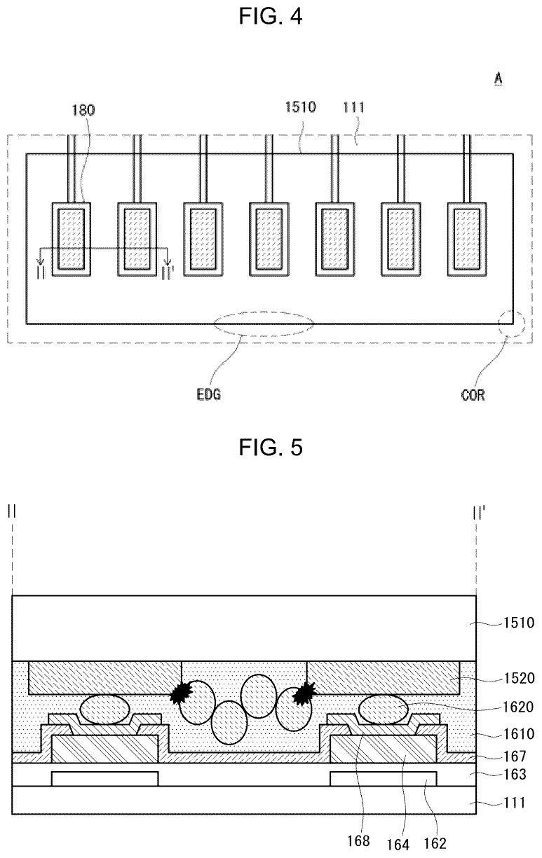

Next, FIG. 4 is a plan view illustrating in detail a region A of FIG. 2, and FIG. 5 is a diagram illustrating an organic light emitting display apparatus taken along line II-II′ of FIG. 2. As illustrated in FIGS. 4 and 5, the organic light emitting display apparatus includes the substrate 111 having the display area and the non-display area at a periphery of the display area.

In FIG. 4, the non-display area includes a display pad 180. In particular, the display pad 180 can be disposed in the non-display area of the substrate 111 to transfer a data signal to data lines of the display area. In the non-display area, the display pad 180 can be electrically connected to a connection electrode 1520 of a driving IC 1510 through a pressure bonding process.

Further, the display pad 180 can include a first electrode layer 162, a second electrode layer 164, and a third electrode layer 168, which are sequentially stacked from the substrate 111. The first electrode layer 162 can include the same metal as that of a gate electrode 132 of the display area. Also, a first insulation layer 163 covering an upper portion of the first electrode layer 162 can be disposed. For example, the first insulation layer 163 can include the same material as that of a gate insulation layer 112 and/or an interlayer insulation layer 114 of the display area. In addition, the first electrode layer 162 and the second electrode layer 164 can be electrically connected to each other through a contact hole of the first insulation layer 163. The second electrode layer 164 can also include the same metal as that of each of source and drain electrodes 136 and 138 of the display area. Further, the third electrode layer 168 can include the same material as that of each of touch electrodes 152e and 154e.

At least one driving IC 1510 and at least one connection electrode 1520 transferring a data signal generated from the driving IC 1510 can be provided on the display pad 180. An adhesive member electrically connecting the connection electrode 1520 to the display pad 180 can be further provided between the connection electrode 1520 and the display pad 180. In particular, the adhesive member can include an adhesive layer 1610 and a conductive ball 1620 which is in the adhesive layer 1610. The connection electrode 1520 of the driving IC 1510 and the display pad 180 on the substrate 111 can be electrically connected to each other by a conductive ball of the adhesive member 1600. Also, the adhesive member can be an anisotropic conductive film (ACF).

In FIG. 4, the driving IC 1510 disposed in the non-display area of the substate 111 can be connected to a plurality of display pads 180 arranged at a certain interval, and an outer portion of the driving IC 1510 formed in a tetragonal shape can include four edge portions EDG and four corner portions COR.

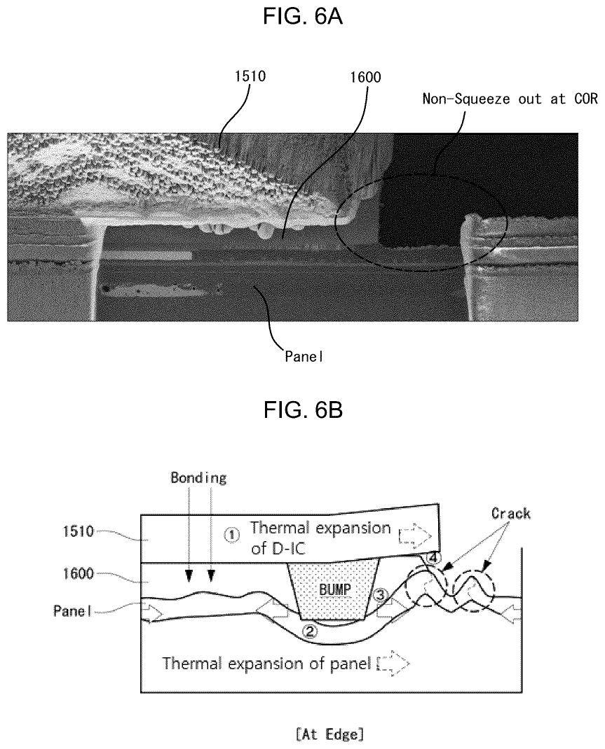

Next, FIG. 6A is a diagram illustrating a cross-sectional view of a portion of an organic light emitting display apparatus according to a comparative example of the present disclosure, and FIG. 6B is a diagram illustrating a perspective view of a portion of the organic light emitting display apparatus according to the comparative example of the present disclosure.

As illustrated in FIG. 6A, in a display apparatus according to the comparative example of the present disclosure, in a process of bonding a driving IC 1510 to a panel through an adhesive member 1600 such as an ACF in a non-display area, a certain pressure is applied to the panel corresponding to a region to which the driving IC 1510 is attached, and due to this, a strain can occur in the panel. When the degree of panel strain is deteriorated, a crack can occur in the panel in the region to which the driving IC 1510 is attached.

In more detail, a panel crack phenomenon near a driving IC attachment portion can be relatively deteriorated more in a corner portion COR of the driving IC 1510 than an edge portion EDG of the driving IC 1510. This can be because the amount of squeeze-out, where the adhesive member 1600 such as an A CF attaching the driving IC 1510 to a substrate including the panel deviates to an outer portion of an attachment portion of the substrate, is relatively more insufficient in the corner portion COR than the edge portion EDG of the driving IC 1510.

That is, because the adhesive member 1600 between the driving IC 1510 and the substrate 111 is not sufficiently squeezed out to a corresponding corner portion COR region, the driving IC is not stably fixed to the substrate including the panel, and therefore, the driving IC 1510 and the panel can thermally expand in a bonding process, causing a panel crack.

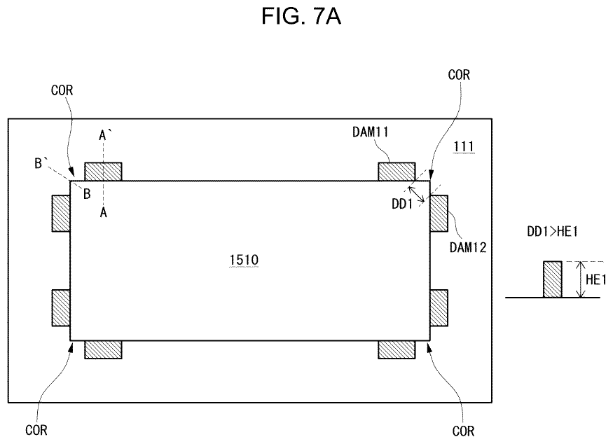

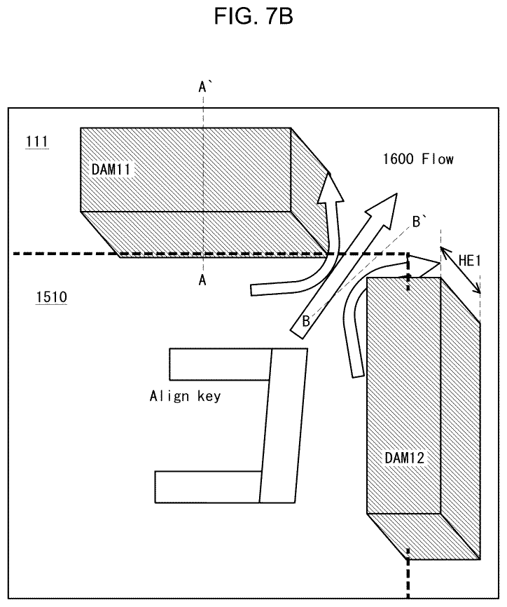

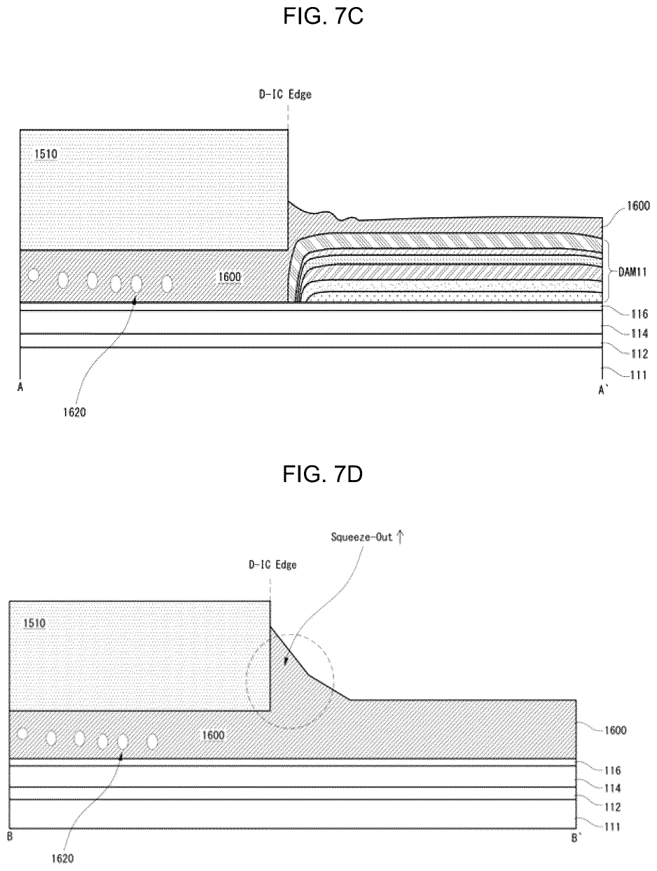

Next, FIG. 7A is a diagram schematically illustrating a plan view of an organic light emitting display apparatus according to a first embodiment of the present disclosure. As illustrated in FIG. 7A, a plurality of dams including a first dam DAM 11 and a second dam DAM 12 are formed in an outer boundary portion of a corner portion COR of a driving IC 1510 in a region where the driving IC 1510 is bonded to a substrate 111 including a panel in a non-display area. In particular, the first dam DAM 11 can be disposed at a first side of the driving IC 1510 with a certain distance with respect to the corner portion COR, and the second dam DAM 12 can be disposed apart from the first dam DAM 11 by a certain interval toward a second side of the driving IC 1510. Each of the first dam DAM 11 and the second dam DAM 12 can also be patterned from a surface of the substrate 111 and can thus be formed to have a certain first height HE1. Because the first dam DAM 11 and the second dam DAM 12 are not disposed at the corner portion COR, a flow path which induces a flow of an adhesive member 1600 to the corner portion COR can be provided in a pressure bonding process. Accordingly, in the pressure bonding process, the adhesive member 1600 such as an A CF attaching the driving IC 1510 to the substrate including the panel toward the corner portion COR of the driving IC 1510 can be easily squeezed out to the corner portion COR along the flow path.

According to the first embodiment of the present disclosure, the first dam DAM 11 and the second dam DAM 12 facing each other with the corner portion COR of the driving IC 1510 therebetween can be disposed apart from each other by a first separation distance DD1. The first separation distance DD1 can be a shortest distance between the first dam DAM 11 and the second dam DAM 12 and be about 30 μm. In this instance, the first height HE1 of each of the first dam DAM 11 and the second dam DAM 12 can be about 10 μm. Because the first separation distance DD1 is greater than the first height HE1, the amount of squeeze-out can increase at the corner portion COR of the driving IC 1510, and thus, stress caused by thermal expansion and contraction can be minimized.

Next, FIG. 7B is a diagram schematically illustrating a perspective view of an organic light emitting display apparatus according to a first embodiment of the present disclosure. As illustrated in FIG. 7B, a first dam DAM 11 can be disposed at a first side of a driving IC 1510 with a certain distance with respect to a corner portion COR of the driving IC 1510 at an outer boundary portion of the driving IC 1510, and a second dam DAM 12 can be disposed apart from the first dam DAM 11 by a certain interval toward a second side of the driving IC 1510.

Moreover, the first dam DAM 11 according to the first embodiment can be disposed to contact a boundary surface of the first side with respect to the corner portion COR of the driving IC 1510, and the second dam DAM 12 can be disposed to contact a boundary surface of the second side with respect to the corner portion COR of the driving IC 1510. Also, each of the first dam DAM 11 and the second dam DAM 12 can be patterned from a surface of a substrate 111 and can thus be formed to have a certain first height HE1, and as shown in FIG. 7B, a flow of the adhesive member 1600 is induced through a flow path formed by the dams so that the adhesive member 1600 such as an A CF attaching the driving IC 1510 to the substrate including the panel toward the corner portion COR of the driving IC 1510 is more easily squeezed out to the corner portion COR of the driving IC 1510 than an edge portion EDG of the driving IC 1510.

That is, in a pressure process between the driving IC 1510 and a display pad, at least a portion of the adhesive member 1600 squeezed out can flow out through the flow path and can be accumulated on a periphery of the corner portion COR of the driving IC 1510. Therefore, in a bonding process of the driving IC 1510, a flow where the adhesive member 1600 between the driving IC 1510 and the substrate 111 flows out to an outer portion of the driving IC 1510 can relatively concentrate in the corner portion COR of the driving IC 1510, and thus, the amount of squeeze-out can increase.

In addition, the amount of squeeze-out of the adhesive member 1600 at the corner portion COR of the driving IC 1510 can increase more than the comparative example described above, and thus, a panel crack occurrence rate in a bonding region of the driving IC 1510 can be considerably reduced.

Next, FIG. 7C is a diagram illustrating an organic light emitting display apparatus taken along line A-A′ of FIG. 7A. As illustrated in FIG. 7C, a first dam DAM 11 and a second dam DAM 12 having a certain height HE1 can be formed through patterning from a surface of a substrate 111 to be symmetrical with both sides with a certain distance with respect to a corner portion COR at an outer boundary portion of a driving IC 150. In addition, the first dam DAM 11 can contact a boundary surface of a first side of the driving IC 1510, and the second dam DAM 12 can contact a boundary surface of a second side of the driving IC 1510. Accordingly, a flow where the adhesive member 1600 such as an ACF flows out to an outer portion of the driving IC 1510 can be small in an edge portion EDG corresponding to the boundary surface of the first side of the driving IC 1510 or the boundary surface of the second side of the driving IC 1510, and thus the amount of squeeze-out of the adhesive member 1600 is less than half of a height of a cross-sectional surface of the driving IC 1510.

Next, FIG. 7D is a diagram schematically illustrating a cross-sectional view of an organic light emitting display apparatus taken along line B-B′ of FIG. 7A. As illustrated in FIG. 7D, a first dam DAM 11 and a second dam DAM 12 having a certain first height HE1 can be formed through patterning from a surface of a substrate 111 at both sides with a certain distance with respect to a corner portion COR at an outer boundary portion of a driving IC 150, and thus, a flow where an adhesive member 1600 such as an A CF attaching the driving IC 1510 to the substrate 111 including a panel flows out to an outer portion of the driving IC 1510 can increase in the corner portion COR of the driving IC 1510 where the first and second dams DAM 11 and DAM 12 are not provided. Accordingly, the amount of squeeze-out of the adhesive member 1600 increases up to a portion near an uppermost end of a cross-sectional height of the driving IC 1510, through a flow path formed by the first dam DAM 11 and the second dam DAM 12.

A Iso, an align key can be additionally provided on the driving IC 1510 included in the organic light emitting display apparatus according to the first embodiment of the present disclosure. The align key can be for an align operation between a display pad and a connection electrode of the driving IC 1510 before a pressure bonding process.

In addition, the first and second dams DAM 11 and DAM 12 included in the organic light emitting display apparatus according to the first embodiment of the present disclosure can be patterned in the same layer and with the same material as an organic insulation layer included in a display area. The first and second dams DAM 11 and DAM 12 can also be formed by stacking a plurality of organic insulation layers. The stacked organic insulation layers can include a plurality of planarization layers and a touch protection layer.

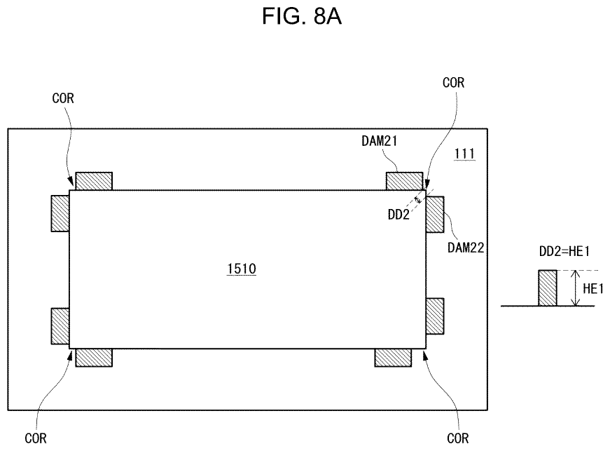

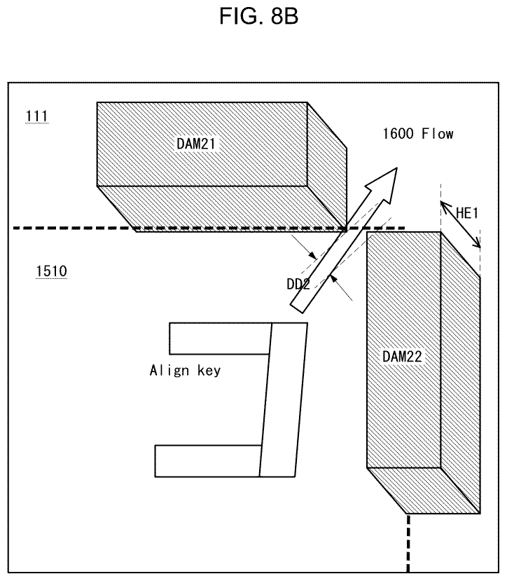

Next, FIG. 8A is a diagram schematically illustrating a plan view of an organic light emitting display apparatus according to a second embodiment of the present disclosure. As illustrated in FIG. 8A, in a display apparatus according to a second embodiment of the present disclosure, a plurality of dams including a first dam DAM 21 and a second dam DAM 22 can be formed in an outer boundary portion of a corner portion COR of a driving IC 1510 in a region where the driving IC 1510 is bonded to a substrate 111 including a panel in a non-display area.

Each of the first dam DAM 21 and the second dam DAM 22 can be patterned from a surface of the substrate 111 and can thus be formed to have a certain first height HE1 with a certain distance with respect to the corner portion COR at an outer boundary portion of the driving IC 1510, and as the corner portion COR is empty, an adhesive member 1600 such as an A CF attaching the driving IC 1510 to the substrate including the panel toward the corner portion COR of the driving IC 1510 can be easily squeezed out to the corner portion COR through a flow path formed by the plurality of dams.

In the display apparatus according to the second embodiment of the present disclosure, a plurality of first dams and second dams DAM 21 and DAM 22 symmetrically formed adjacent to the corner portion COR of the driving IC 1510 can be apart from each other by a second separation distance DD2, and the second separation distance DD2 can be equal to a first height HE1, which is about 10 μm, of each of the first and second dams DAM 21 and DAM 22. The second separation distance DD2 can be a shortest distance between the first and second dams DAM 21 and DAM 22. When the second separation distance DD2 is equal to the first height HE1, the amount of squeeze-out of the adhesive member 1600 can concentrate more in the corner portion COR in a pressure bonding process, and thus, stress caused by thermal expansion and contraction can be more effectively reduced.

Moreover, the first dam DAM 21 according to the second embodiment can be disposed adjacent to a boundary surface of a first side with respect to the corner portion COR of the driving IC 1510, and the second dam DAM 22 can be disposed to contact a boundary surface of a second side with respect to the corner portion COR of the driving IC 1510.

As illustrated in FIG. 8B, a first dam DAM 21 and a second dam DAM 22 can be formed to have a certain first height HE1 through patterning from a surface of a substrate 111 at both sides with a certain distance with respect to a corner portion COR at an outer boundary portion of a driving IC 150, and a space of the corner portion COR of the driving IC 1510 where the first and second dams DAM 21 and DAM 22 are not provided can be reduced more than a space of the corner portion COR according to the first embodiment. Accordingly, in a pressure bonding process, a flow where an adhesive member 1600 flows out to an outer portion of the driving IC 1510 can concentrate in a corner portion region which is relatively narrow. In addition, an align key can be additionally provided on the driving IC 1510 included in the organic light emitting display apparatus according to the second embodiment of the present disclosure.

Further, the first and second dams DAM 21 and DAM 22 included in the organic light emitting display apparatus according to the second embodiment of the present disclosure can be patterned in the same layer and with the same material as an organic insulation layer included in a display area. The first and second dams DAM 21 and DAM 22 can also be formed by stacking a plurality of organic insulation layers. Further, the stacked organic insulation layers can include a plurality of planarization layers and a touch protection layer.

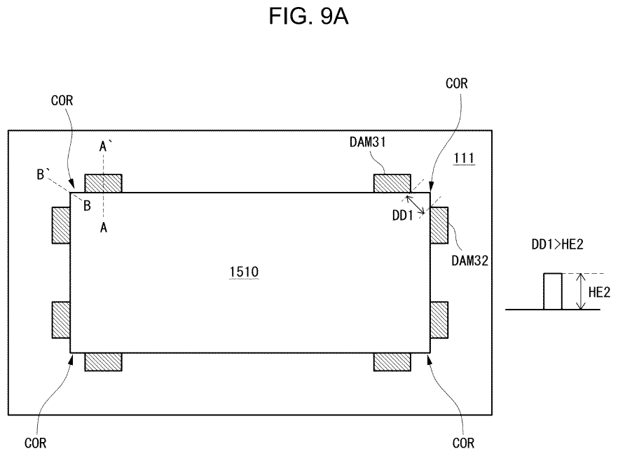

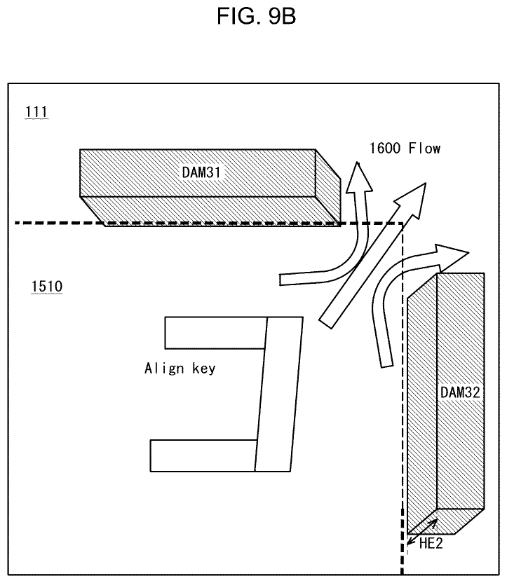

Next, FIG. 9A is a diagram schematically illustrating a plan view of an organic light emitting display apparatus according to a third embodiment of the present disclosure. As illustrated in FIG. 9A, in a display apparatus according to a third embodiment of the present disclosure, a plurality of dams including a first dam DAM 31 and a second dam DAM 32 can be formed in an outer boundary portion of a corner portion COR of a driving IC 1510 in a region where the driving IC 1510 is bonded to a substrate 111 including a panel in a non-display area. Each of the first dam DAM 31 and the second dam DAM 32 can be patterned from a surface of the substrate 111 and can thus be formed to have a certain second height HE2 with a certain distance DD1 with respect to the corner portion COR at an outer boundary portion of the driving IC 1510, and as the corner portion COR is empty, an adhesive member 1600 such as an ACF attaching the driving IC 1510 to the substrate including the panel toward the corner portion COR of the driving IC 1510 can be easily squeezed out to the corner portion COR through a flow path formed by the plurality of dams.

In the display apparatus according to the third embodiment of the present disclosure, a plurality of first dams and second dams DAM 31 and DAM 32 symmetrically formed adjacent to the corner portion COR of the driving IC 1510 can be apart from each other by a first separation distance DD1, and the first separation distance DD1 can be greater than a second height HE2 which is about 5 μm.

In the display apparatus according to the third embodiment of the present disclosure, the second height HE2 of each of the first dams and second dams DAM 31 and DAM 32 can be reduced by a thickness of a touch protection layer in a case where a touch function is not applied. That is, the touch protection layer can be excluded from a stack configuration of organic insulation layers configuring the first dams and second dams DAM 31 and DAM 32. As illustrated in FIG. 9B, a space of the corner portion COR of the driving IC 1510 where the first dams and second dams DAM 31 and DAM 32 are not provided can be widely formed compared to the height HE2 of the first dams and second dams DAM 31 and DAM 32 formed through patterning from the surface of the substrate 111 to be symmetrical with both sides with a certain distance with respect to the corner portion COR in an outer boundary portion of the driving IC 1510, and thus, a flow where the adhesive member 1600 such as an ACF attaching the driving IC 1510 to the substrate 111 including the panel flows out to an outer portion of the driving IC 1510 can relatively concentrate.

Moreover, the first dam DAM 31 according to the third embodiment can be disposed to contact a boundary surface of the first side with respect to the corner portion COR of the driving IC 1510, and the second dam DAM 32 can be disposed to contact a boundary surface of the second side with respect to the corner portion COR of the driving IC 1510. An align key can also be additionally provided on the driving IC 1510 included in the organic light emitting display apparatus according to the third embodiment of the present disclosure.

A Iso, the first and second dams DAM 31 and DAM 32 included in the organic light emitting display apparatus according to the third embodiment of the present disclosure can be patterned in the same layer and with the same material as an organic insulation layer included in a display area.

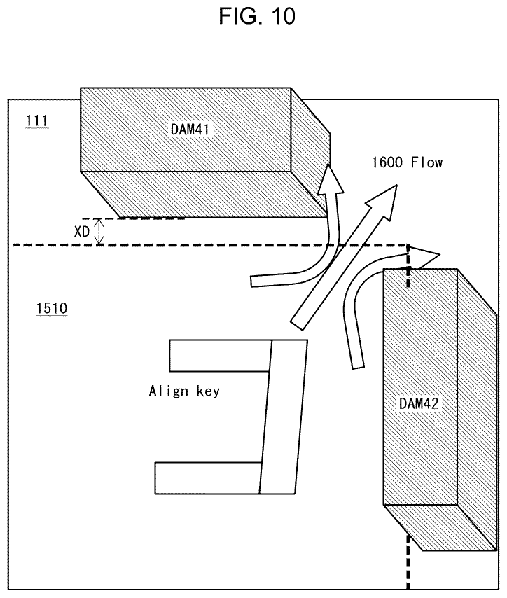

Next, FIG. 10 is a diagram schematically illustrating a perspective view of an organic light emitting display apparatus according to a fourth embodiment of the present disclosure. As illustrated in FIG. 10, in a display apparatus according to a fourth embodiment of the present disclosure, a plurality of dams including a first dam DAM 41 and a second dam DAM 42 can be formed in an outer boundary portion of a corner portion COR of a driving IC 1510 in a region where the driving IC 1510 is bonded to a substrate 111 including a panel in a non-display area. Each of the first dam DAM 41 and the second dam DAM 42 can be formed apart from a boundary surface configuring an edge portion EDG by a certain distance XD at the outer boundary portion of the driving IC 1510, and as the corner portion COR is empty, an adhesive member 1600 such as an A CF attaching the driving IC 1510 to the substrate including the panel toward the corner portion COR of the driving IC 1510 can be easily squeezed out through a flow path formed by the plurality of dams.

The display apparatus according to the fourth embodiment of the present disclosure can have a structure where a position of a dam is provided at a position apart from the edge portion EDG of the driving IC by the certain distance XD so as to increase an align margin in a process of bonding the driving IC to the panel in the non-display area. An align key can also be additionally provided on the driving IC 1510 included in the organic light emitting display apparatus according to the fourth embodiment of the present disclosure.

In addition, the first and second dams DAM 41 and DAM 42 included in the organic light emitting display apparatus according to the fourth embodiment of the present disclosure can be patterned in the same layer and with the same material as an organic insulation layer included in a display area.

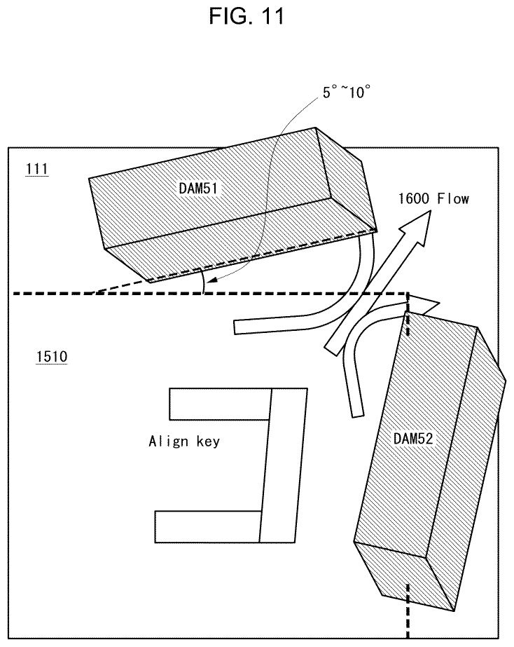

Next, FIG. 11 is a diagram schematically illustrating a perspective view of an organic light emitting display apparatus according to a fifth embodiment of the present disclosure. As illustrated in FIG. 11, in a display apparatus according to a fifth embodiment of the present disclosure, a plurality of dams including a first dam DAM 51 and a second dam DAM 52 can be formed in an outer boundary portion of a corner portion COR of a driving IC 1510 in a region where the driving IC 1510 is bonded to a substrate 111 including a panel in a non-display area.

The first dam DAM 51 can be disposed to be inclined by a certain angle with respect to a boundary surface configuring an edge portion EDG at an outer boundary portion of a first side with respect to a corner portion COR of a driving IC 1510, and the second dam DAM 52 can be disposed to be inclined by a certain angle with respect to the boundary surface configuring the edge portion EDG at an outer boundary portion of a second side with respect to the corner portion COR of the driving IC 1510. The certain angle can be the same or different for the first and second dams. In addition, only one of the dams can be inclined at the certain angle and the other dam can be parallel to the boundary surface (i.e., having a zero certain angle). In addition, the inner surface of a dam can have a curvature further promoting the flow of the adhesive. The curvature can include a concave curvature flowing the adhesive towards the corner portion. The heights of the dams can be the same or different from each other.

As described above, the first and second dams DAM 51 and DAM 52 can be formed to be inclined by a certain angle with respect to a boundary surface of the driving IC 1510, and thus, an adhesive member 1600 such as an A CF attaching the driving IC 1510 to the substrate including the panel toward the corner portion COR of the driving IC 1510 can be easily squeezed out through a flow path formed by the plurality of dams.

In addition, the display apparatus according to a fifth embodiment of the present disclosure can be characterized in that the amount of squeeze-out of the adhesive member 1600, such as an ACF attaching the driving IC 1510 to the substrate including the panel toward the corner portion COR of the driving IC 1510, to the outside of the driving IC 1510 is easily adjusted according to a unique characteristic based on the kind and size of each application. An align key can also be additionally provided on the driving IC 1510 included in the organic light emitting display apparatus according to the fifth embodiment of the present disclosure.

In addition, the first and second dams DAM 51 and DAM 52 included in the organic light emitting display apparatus according to the fifth embodiment of the present disclosure can be patterned in the same layer and with the same material as an organic insulation layer included in a display area.

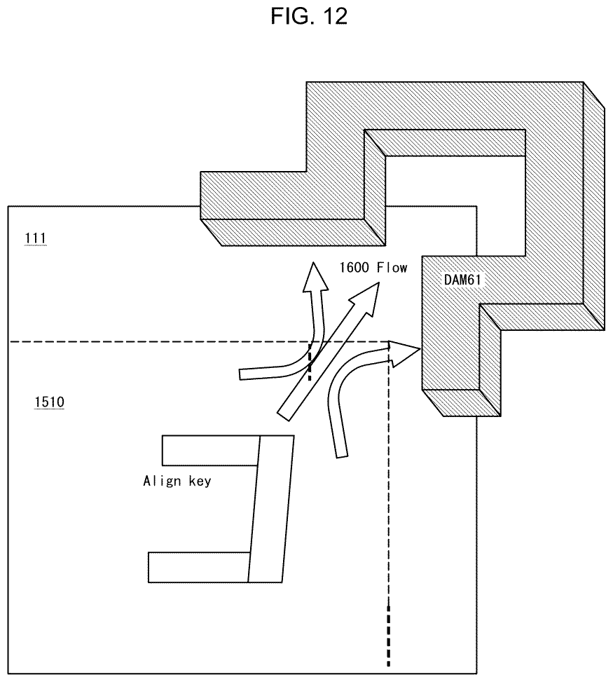

Next, FIG. 12 is a diagram schematically illustrating a perspective view of an organic light emitting display apparatus according to a sixth embodiment of the present disclosure. As illustrated in FIG. 12, in a display apparatus according to a sixth embodiment of the present disclosure, a plurality of dams including a first dam DAM 61 and a second dam DAM 62 can be formed in an outer boundary portion of a corner portion COR of a driving IC 1510 in a region where the driving IC 1510 is bonded to a substrate 111 including a panel in a non-display area.

Further, the corner portion COR of the driving IC 1510 can be empty, and the first dam DAM 61 and the second dam DAM 62 can be formed to include an extension portion of a fence shape in a certain region with respect to the corner portion COR, and thus, a range can be set where an adhesive member 1600 such as an ACF attaching the driving IC 1510 to the substrate including the panel toward the corner portion COR of the driving IC 1510 is easily squeezed out. In this instance, an area of a fence region can be appropriately adjusted according to a unique characteristic based on the kind and size of each application.

Here, the extension portion of a fence shape can be formed in a shape where one end of the first dam DAM 61 is connected to one end of the second dam DAM 62 and can be formed in a structure which surrounds the corner portion COR of the driving IC 1510. An align key can also be additionally provided on the driving IC 1510 included in the organic light emitting display apparatus according to the sixth embodiment of the present disclosure.

Further, the first and second dams DAM 61 and DAM 62 included in the organic light emitting display apparatus according to the sixth embodiment of the present disclosure can be patterned in the same layer and with the same material as an organic insulation layer included in a display area.

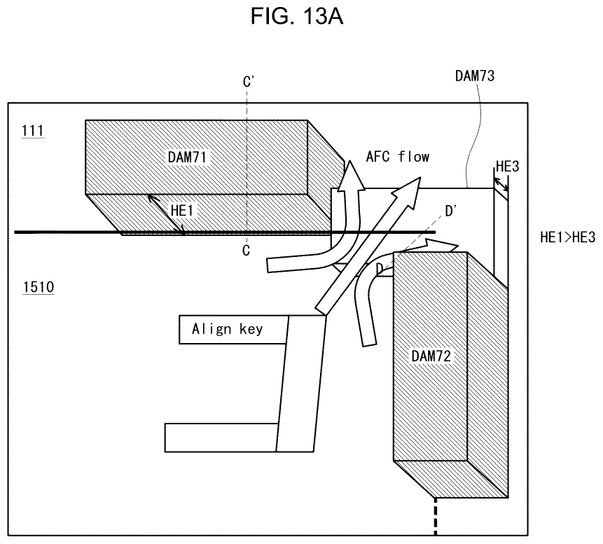

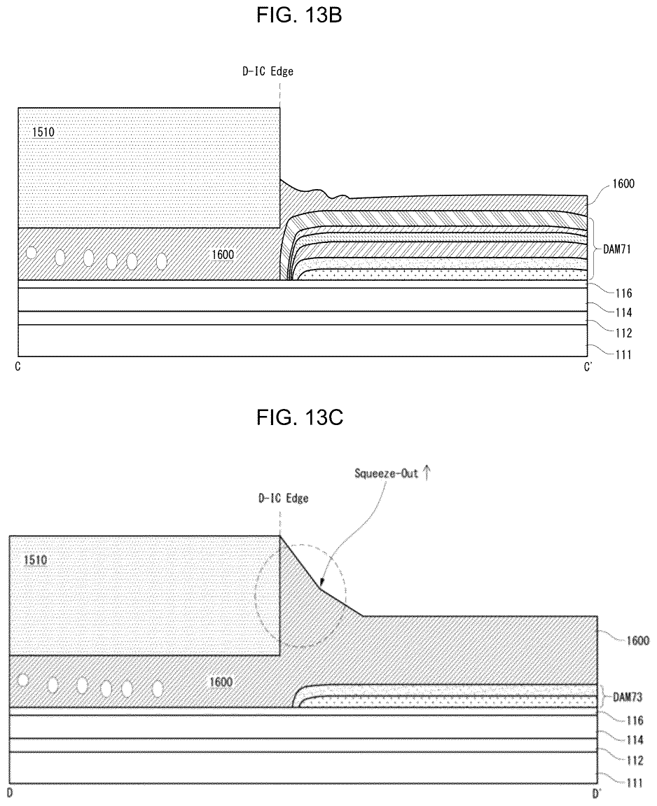

Next, FIG. 13A is a diagram schematically illustrating a perspective view of an organic light emitting display apparatus according to a seventh embodiment of the present disclosure. As illustrated in FIG. 13A, in a display apparatus according to a seventh embodiment of the present disclosure, a plurality of dams including a first dam DAM 71 and a second dam DAM 72 can be formed in an outer boundary portion of a corner portion COR of a driving IC 1510 in a region where the driving IC 1510 is bonded to a substrate 111 including a panel in a non-display area.

Moreover, an auxiliary dam DAM 73 can be installed in the corner portion COR of the driving IC 1510, and thus, an adhesive member 1600 such as an A CF attaching the driving IC 1510 to the substrate including the panel toward the corner portion COR of the driving IC 1510 can be easily squeezed out through a flow path formed by the first dam DAM 71 and the second dam DAM 72.

The auxiliary dam DAM 73 can be disposed between the first dam DAM 71 and the second dam DAM 72 and can be disposed to overlap the corner portion COR of the driving IC 1510. For easy squeeze-out, a height HE3 of the auxiliary dam DAM 73 can be formed to be less than a height HE1 of each of the first dam DAM 71 and the second dam DAM 72.

Next, FIG. 13B is a diagram schematically illustrating a cross-sectional view of an organic light emitting display apparatus taken along line C-C′ of FIG. 13A. As illustrated in FIG. 13B, a first dam DAM 71 and a second dam DAM 72 having a certain height HE1 can be formed through patterning from a surface of a substrate 111 to be symmetrical with both sides with a certain distance with respect to a corner portion COR at an outer boundary portion of a driving IC 150. Accordingly, a flow where an adhesive member 1600 such as an ACF flows out to an outer portion of the driving IC 1510 can be small in an edge portion EDG of the driving IC 1510, and thus, it can be seen that the amount of squeeze-out of the adhesive member 1600 is less than half of a height of a cross-sectional surface of the driving IC 1510.

Next, FIG. 13C is a diagram schematically illustrating a cross-sectional view of an organic light emitting display apparatus taken along line D-D′ of FIG. 13A. As illustrated in FIG. 13C, a first dam DAM 71 and a second dam DAM 72 having a certain height HE1 can be formed through patterning from a surface of a substrate 111 to be symmetrical with both sides with a certain distance with respect to a corner portion COR at an outer boundary portion of a driving IC 150, and thus, a separate auxiliary dam DAM 73 can be installed in the corner portion COR of the driving IC 1510. Accordingly, a flow where an adhesive member 1600 such as an A CF attaching the driving IC 1510 to the substrate 111 including a panel flows out to an outer portion of the driving IC 1510 can increase by a volume of the auxiliary dam DAM 73, and thus, it can be seen that the amount of squeeze-out of the adhesive member 1600 increases up to a portion near an uppermost end of a cross-sectional height of the driving IC 1510.

In addition, an align key can be additionally provided on the driving IC 1510 included in the organic light emitting display apparatus according to the seventh embodiment of the present disclosure. Also, the first and second dams DAM 71 and DAM 72 included in the organic light emitting display apparatus according to the seventh embodiment of the present disclosure can be patterned in the same layer and with the same material as an organic insulation layer included in a display area.

A display apparatus according to an embodiment of the present disclosure can include a substrate which includes a display area and a non-display area at a periphery of the display area, a plurality of display pads which is provided in the non-display area and is configured to transfer a signal to the display area, an insulation layer which covers an upper portion of the substrate and some of the plurality of display pads, a driving IC which is electrically connected to the display pad and is disposed in the non-display area, and a plurality of dams which are disposed in a peripheral region of the driving IC and is formed to have a certain height from a surface of the substrate.

According to the present disclosure, a problem can be solved where a crack occurs in a panel corner portion due to thermal expansion or contraction, in a process of bonding a driving IC to a panel through an adhesive member such as an anisotropic conductive film (ACF) in a non-display area.

According to the present disclosure, when the driving IC is mounted on a substrate, an adhesive member between the driving IC and a display pad can be sufficiently squeezed out from a corner portion, thereby minimizing stress caused by thermal expansion and contraction occurring in a bonding process of the driving IC. As a result, a display defect of a display apparatus can be prevented, thereby providing an organic light emitting display apparatus having improved reliability.

The effects according to the present disclosure are not limited to the above examples, and other various effects can be included in the specification.

While the present disclosure has been particularly shown and described with reference to exemplary embodiments thereof, it will be understood by those of ordinary skill in the art that various changes in form and details can be made therein without departing from the spirit and scope of the present disclosure as defined by the following claims.

What is claimed is:

1. An organic light emitting display apparatus comprising:
a substrate including a display area and a non-display area at a periphery of the display area;
a plurality of display pads provided in the non-display area and configured to transfer a signal to the display area;
a driving integrated circuit (IC) electrically connected to the plurality of display pads through an adhesive member in the non-display area;
a first dam disposed at a first corner portion of the driving IC; and
a second dam disposed at the first corner portion of the driving IC,
wherein the first dam and the second dam are spaced apart from each other with the first corner portion of the driving IC therebetween to form an adhesive flow path between the first dam and the second dam, and
wherein the adhesive member is disposed in the adhesive flow path formed between the first dam and the second dam.

2. The organic light emitting display apparatus of claim 1, wherein the first dam is disposed at a first side of the driving IC with respect to the first corner portion of the driving IC, and the second dam is disposed at a second side of the driving IC with respect to the first corner portion of the driving IC and is spaced apart from the first dam by a certain interval.

3. The organic light emitting display apparatus of claim 2, wherein the first dam and the second dam have a same height, and
wherein the certain interval between the first dam and the second dam is greater than the same height of the first dam and the second dam.

4. The organic light emitting display apparatus of claim 2, wherein the first dam and the second dam have a same height, and
wherein the certain interval between the first dam and the second dam is different than the same height of the first dam and the second dam.

5. The organic light emitting display apparatus of claim 2, wherein the first dam contacts a boundary surface of the first side of the driving IC, and the second dam contacts a boundary surface of the second side of the driving IC.

6. The organic light emitting display apparatus of claim 2, wherein the first dam is spaced apart from a boundary surface of the first side of the driving IC, and the second dam is spaced apart from a boundary surface of the second side of the driving IC.

7. The organic light emitting display apparatus of claim 2, wherein the first dam is inclined by a first angle with respect to a boundary surface of the first side of the driving IC, and
wherein the second dam is inclined by a second angle with respect to a boundary surface of the second side of the driving IC.

8. The organic light emitting display apparatus of claim 7, wherein the first angle is equal to the second angle.

9. The organic light emitting display apparatus of claim 7, wherein the first angle is different than the second angle.

10. The organic light emitting display apparatus of claim 2, wherein the first dam is inclined by an angle with respect to a boundary surface of the first side of the driving IC, and
wherein the second dam is parallel to a boundary surface of the second side of the driving IC.

11. The organic light emitting display apparatus of claim 1, wherein the first dam and the second dam have different heights.

12. The organic light emitting display apparatus of claim 2, wherein an inner side surface of at least one of the first dam and the second dam has a curved surface.

13. The organic light emitting display apparatus of claim 12, wherein the curved surface comprises a concave surface with respect to a boundary surface of the first side of the driving IC.

14. The organic light emitting display apparatus of claim 1, wherein the first dam is disposed in parallel to a first side of the driving IC with respect to the first corner portion of the driving IC, and the second dam is disposed in parallel to a second side of the driving IC with respect to the first corner portion of the driving IC.

15. The organic light emitting display apparatus of claim 14, wherein an inner side surface of at least one of the first dam and the second dam is inclined by an angle with respect to the first side of the driving IC.

16. The organic light emitting display apparatus of claim 1, further comprising:
a third dam disposed at a second corner portion of the driving IC; and
a fourth dam disposed at the second corner portion of the driving IC,
wherein the third dam and the fourth dam are spaced apart from each other with the second corner portion of the driving IC therebetween to form another adhesive flow path between the third dam and the fourth dam.

17. The organic light emitting display apparatus of claim 16, wherein the adhesive member is further disposed in the another adhesive flow path formed between the second dam and the third dam.

18. The organic light emitting display apparatus of claim 1, wherein the first dam and the second dam further comprise a fence-shaped extension portion connecting one end of the first dam to one end of the second dam, and
wherein the fence-shaped extension portion surrounds the first corner portion of the driving IC.

19. The organic light emitting display apparatus of claim 1, further comprising:
an auxiliary dam disposed between the first dam and the second dam,
wherein the auxiliary dam overlaps the first corner portion of the driving IC, and
wherein a height of the auxiliary dam is less than a height of each of the first dam and the second dam.

20. The organic light emitting display apparatus of claim 19, wherein the first dam, the auxiliary dam and the second dam includes a stack of first organic insulation layers provided in a same layer and including a same material as a plurality of second organic insulation layers provided in the display area.
